(19) United States
(12) Patent Application Publication
(10) Pub. No.: US 2009/0001577 A1
(43) Pub. Date: Jan. 1, 2009

(54) METAL LINE OF SEMICONDUCTOR DEVICE WITH A TRIPLE LAYER DIFFUSION BARRIER AND METHOD FOR FORMING THE SAME

(76) Inventors: Jeong Tae KIM, Gyeonggi-do (KR); Seung Jin YEOM, Gyeonggi-do (KR); Baek Mann KIM, Gyeonggi-do (KR); Young Jin LEE, Gyeonggi-do (KR); Dong Ha JUNG, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 11/939,054

(22) Filed: Nov. 13, 2007

(30) Foreign Application Priority Data
Jun. 26, 2007 (KR) 10-2007-0063247

(51) Int. Cl. H01L 23/532; H01L 21/4763

(52) U.S. Cl. 257/751; 438/653; 257/E23.141; 257/E21.495

(57) ABSTRACT

A metal line in a semiconductor device includes an insulation layer formed on a semiconductor substrate. A metal line forming region is formed in the insulation layer. A diffusion barrier is formed on a surface of the metal line forming region and a metal line is formed to fill the metal line forming region of the insulation layer. The diffusion barrier is formed between the metal line and the insulation layer. The diffusion barrier has a structure in which a TaSiₓN_{y} layer is interposed between a first Ta-based layer and a second Ta-based layer. A metal line formed in this manner prevents the contact resistance of the metal line from increasing and the leakage current characteristics from degrading, thereby improving the device characteristics and reliability.

### CROSS-REFERENCE TO RELATED APPLICATIONS

The present application claims priority to Korean patent application number 10-2007-0063247 filed on Jun. 26, 2007, which is incorporated herein by reference in its entirety.

### BACKGROUND OF THE INVENTION

The present invention relates to a metal line of a semiconductor device and a method for forming the same, and more particularly, to a metal line of a semiconductor device which can improve diffusion barrier characteristics and a method for forming the same.

In general, materials used for the metal line of a semiconductor device include aluminum (Al) and tungsten (W). These materials have been used mainly due to their good electrical conductivity. Recently, research has been directed towards the use of copper (Cu) as a next-generation material for a metal line. Copper has excellent electrical conductivity and low resistance compared to aluminum and tungsten. Therefore, copper can solve problems associated with an RC signal delay in the semiconductor devices that are highly integrated and operating at a high speed.

However, copper cannot be easily dry-etched into a wiring pattern. As such, in order to form a metal line using copper, a damascene process is employed. In the damascene process, a metal line is formed by first etching an interlayer dielectric to define a metal line forming region. After completion of the metal line forming region a copper layer is then filled in the metal line forming region.

Unlike aluminum, copper diffuses through the interlayer dielectric. If copper diffuses to the semiconductor substrate, the diffused copper acts as deep-level impurities and induces a leakage current. Therefore, when forming a copper metal line using the damascene process, a diffusion barrier for preventing diffusion of copper must be formed on the surface of the metal line forming region which will come into contact with a copper layer. Generally, the diffusion barrier is made of a Ta layer, a TaN layer, or a Ta/TaN layer.

However, problems are known to occur in the conventional art when the diffusion barrier made of a Ta layer, a TaN layer, or a Ta/TaN layer, is applied to the manufacture of an ultra-highly integrated semiconductor device below 40 nm, such as an increase in the contact resistance and degradation of the leakage current characteristics.

In the case of ultra-highly integrated semiconductor devices that are below 40 nm (which exceeds the current technology), the size of a contact hole for a metal line decreases. Since the diffusion barrier must have a minimum thickness to properly perform its function, the proportion of copper in the contact hole decreases, and therefore, the contact resistance increases. Conversely, if the thickness of the diffusion barrier is reduced to prevent the contact resistance from increasing, the diffusion barrier cannot properly perform its function and a leakage current is then induced.

Accordingly, in the conventional art in which the diffusion barrier is made of a Ta layer, a TaN layer or a Ta/TaN layer, the characteristics and the reliability of the semiconductor devices are likely to be deteriorated due to either the increase in contact resistance or degraded leakage current characteristics.

### SUMMARY OF THE INVENTION

Embodiments of the present invention are directed to a metal line of a semiconductor device that can improve the characteristics of a diffusion barrier and a method for forming the same.

Also, embodiments of the present invention are directed to a metal line of a semiconductor device that can improve the characteristics of a diffusion barrier and thereby improve the characteristics and reliability of a semiconductor device and a method for forming the same.

In one aspect, a semiconductor device having a metal line comprises an insulation layer formed on a semiconductor substrate and having a metal line forming region formed in the insulation layer; a diffusion barrier formed on the surfaces of the metal line forming region; a metal line formed to fill the metal line forming region; wherein the diffusion barrier has a structure in which a TaSiₓN_{y} layer is interposed between a first Ta-based layer and a second Ta-based layer.

The metal line forming region has a structure including a trench or a trench and a via hole formed in the trench.

The first and second Ta-based layers can be made of a Ta layer or a TaN layer.

The first and second Ta-based layers have a thickness of 10˜50 Å.

In the TaSiₓN_{y} layer, x has a range of 0.1˜0.9 and y has a range of 0.1˜0.9, provided x+y=1.

The TaSiₓN_{y} layer has a thickness of 5˜20 Å.

The TaSiₓN_{y} layer contains silicon of 1˜5 wt %.

The metal line is made of a copper layer.

In another aspect, a method for forming the metal line of a semiconductor device comprises the steps of: forming an insulation layer on a semiconductor substrate and forming a metal line forming region therein; forming a diffusion barrier on a surface of the metal line forming region and insulation layer to have a structure in which a TaSiₓN_{y} layer is interposed between a first Ta-based layer and a second Ta-based layer; forming a metal layer on the diffusion barrier to fill the metal line forming region; and removing the metal layer and the diffusion barrier until the insulation layer is exposed.

The metal line forming region is formed to have a structure including a trench or a trench and a via hole.

The first and second Ta-based layers can be made of a Ta layer or a TaN layer.

The first and second Ta-based layers are formed to have a thickness of 10˜50 Å.

In the TaSiₓN_{y} layer, x has a range of 0.1˜0.9 and y has a range of 0.1˜0.9, provided x+y=1.

The TaSiₓN_{y} layer is formed to have a thickness of 5˜20 Å.

The TaSiₓN_{y} layer is formed to contain silicon of 1˜5 wt %.

The TaSiₓN_{y} layer is formed by surface-treating the first Ta-based layer.

When the first Ta-based layer is a Ta layer, the TaSiₓN_{y} layer is formed by surface-treating the Ta layer using SiH₄ gas and nitrogen-containing gas or SiH₂Cl₂ gas and nitrogen-containing gas.

When the Ta-based layer is a TaN layer, the TaSiₓN_{y} layer is formed by surface-treating the TaN layer using SiH₄ gas or SiH₂Cl₂ gas.

The above surface treatment can be implemented through any one of rapid thermal processing (RTP), furnace annealing and plasma treatment.

The metal layer is made of a copper layer.

### BRIEF DESCRIPTION OF THE DRAWINGS

FIG. 1 is a cross-sectional view illustrating a metal line of a semiconductor device in accordance with an embodiment of the present invention.

FIGS. 2A through 2F are cross-sectional views illustrating the processes of a method for forming a metal line of a semiconductor device in accordance with another embodiment of the present invention.

### DESCRIPTION OF SPECIFIC EMBODIMENTS

In the present invention, when forming a metal line using a copper layer, a TaSiₓN_{y} layer is interposed between a first Ta-based layer and a second Ta-based layer to form a triple layered structure. This triple layered structure is formed as the diffusion barrier.

The diffusion barrier having a triple layer of Ta/TaSiₓN_{y}/Ta or TaN/TaSiₓN_{y}/TaN, in which the TaSiₓN_{y} layer is interposed between the first Ta-based layer and the second Ta-based layer, can attain improved interfacial screening effect when compared to a conventional single layer diffusion barrier. Accordingly, the diffusion barrier having the triple-layered structure (in which the TaSiₓN_{y} layer is interposed between the first Ta-based layer and the second Ta-based layer) has improved characteristics by itself. As a result, it is possible to prevent both the contact resistance of the copper metal line from increasing and the leakage current characteristics thereof from being degraded, thus improving the characteristics and reliability of a semiconductor device.

Hereafter, the specific embodiments of the present invention will be described in detail with reference to the attached drawings.

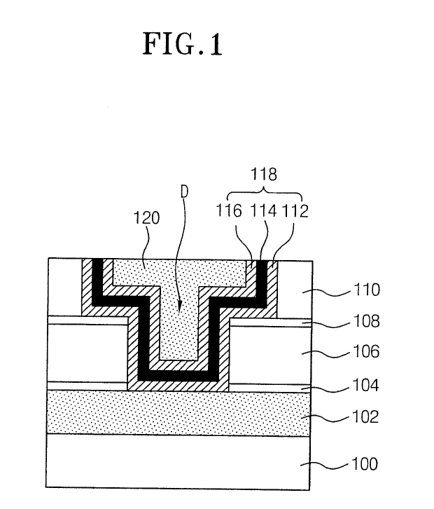

FIG. 1 is a cross-sectional view illustrating a metal line of a semiconductor device in accordance with an embodiment of the present invention.

Referring to FIG. 1, a lower metal line 102 is formed on a semiconductor substrate 100. A first etch stop layer 104, a first insulation layer 106, a second etch stop layer 108, and a second insulation layer 110 are sequentially formed over the semiconductor substrate 100 including the lower metal line 102. A metal line forming region D, in which an upper metal line is to be formed, is defined in the first etch stop layer 104, the first insulation layer 106, the second etch stop layer 108 and the second insulation layer 110 to expose the lower metal line 102.

The first and second etch stop layers 104 and 108 are made of SiN. The metal line forming region D can be either defined to have a single structure having a single trench or a dual structure having a trench and at least one via hole communicating with the trench. In the present embodiment shown in FIG. 1, a metal line forming region D having the dual structure is shown.

A diffusion barrier 118 is formed on the surface of the meal line forming region D, and an upper metal line 120 is formed on the diffusion barrier 118 to fill the metal line forming region D. The upper metal line is in electrical contact with the lower metal line 102. The diffusion barrier 118 has a triple-layered structure in which a TaSiₓN_{y} layer 114 is interposed between a first Ta-based layer 112 and a second Ta-based layer 116. The first and second Ta-based layers 112 and 116 comprise Ta layers or TaN layers, and preferably, TaN layers. Hence, the diffusion barrier 118 according to the present invention has a triple layer of TaN/TaSiₓN_{y}/TaN or Ta/TaSiₓN_{y}/Ta.

The first Ta-based layer 112, the TaSiₓN_{y} layer 114, and the second Ta-based layer 116 are formed to have the thicknesses in the range of 10˜50 Å, 5˜20 Å, and 10˜50 Å, respectively. The TaSiₓN_{y} layer 114 is formed through a surface treatment of the first Ta-based layer 112. The surface treatment is implemented through any one of rapid thermal processing (RTP), furnace annealing and plasma treatment. The TaSiₓN_{y} layer 114 is formed to contain silicon of 1˜5 wt %. In the TaSiₓN_{y} layer 114, x has a range of 0.1˜0.9 and y has a range of 0.1˜0.9 provided x+y=1. The upper metal line 120 is made of a copper layer.

In the metal line of a semiconductor device according to an embodiment of the present invention, the diffusion barrier having a triple layer of Ta/TaSiₓN_{y}/Ta or TaN/TaSiₓN_{y}/TaN would lead to an improved interfacial screening effect compared to the conventional single layer diffusion barriers. Accordingly, the diffusion barrier according to an embodiment of the present invention has improved characteristics by itself. As a result, the novel multiple-layered diffusion barrier as disclosed in the embodiments of the present invention, the problems relating to increased contact resistance in the copper metal line and the degradation of the leakage current characteristics. Therefore, the present invention improves upon the characteristics and reliability of a semiconductor device.

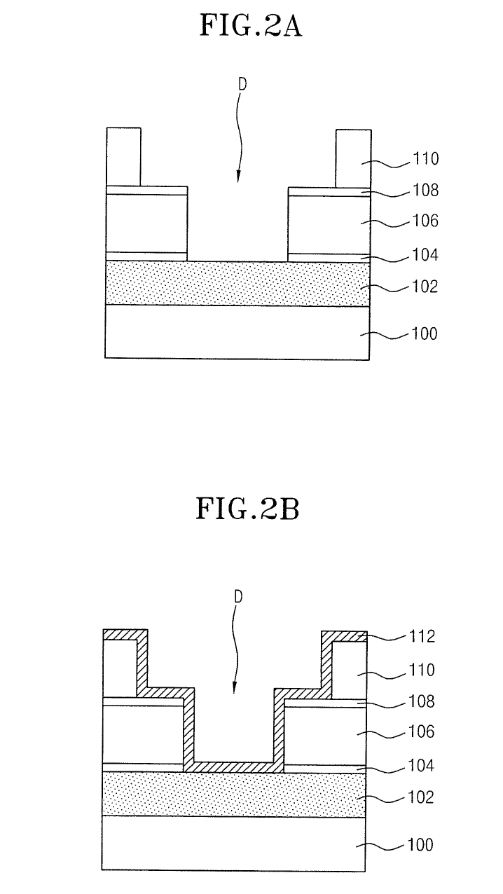

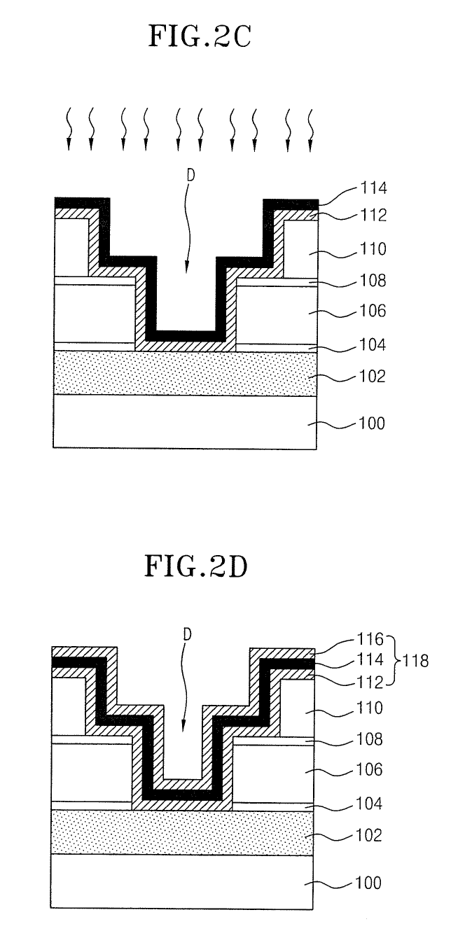

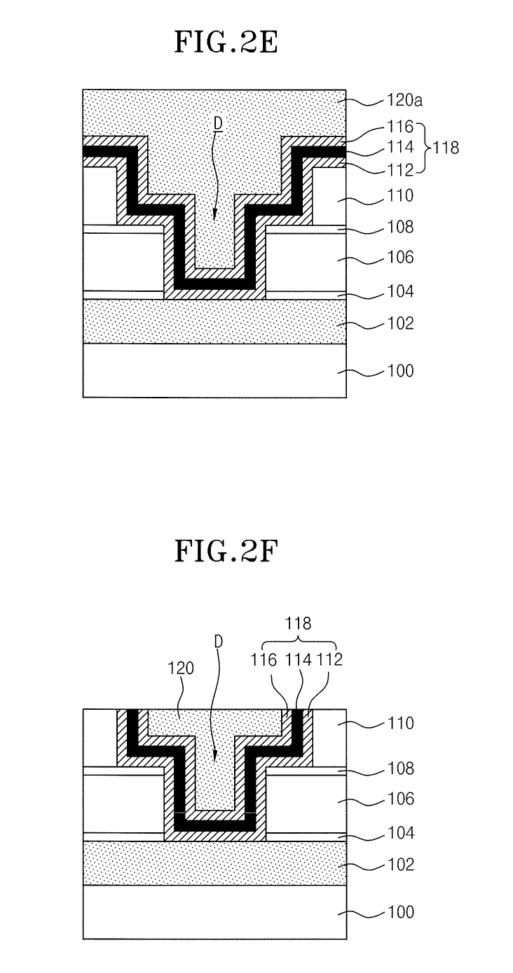

FIGS. 2A through 2F are cross-sectional views in connection with illustrating the processes for forming a metal line of a semiconductor device in accordance with another embodiment of the present invention.

Referring to FIG. 2A, a lower metal line 102 is formed on a semiconductor substrate 100 which has a structure including gate lines and bit lines. A first etch stop layer 104, a first insulation layer 106, a second etch stop layer 108, and a second insulation layer 110 are sequentially formed over the semiconductor substrate 100 having the lower metal line 102. The first and second etch stop layers 104 and 108 are made of a SiN layer.

The second insulation layer 110, the second etch stop layer 108, the first insulation layer 106, and the first etch stop layer 104 are then etched to form a metal line forming region D, in which an upper metal line is to be formed. The metal line forming region is defined to expose the lower metal line 102. The metal line forming region D can be defined to have a single structure having a single trench or a dual structure having a trench and at least one via hole communicating with the trench. Preferably, and as shown in the present embodiment of FIGS. 2A-2F, the metal line forming region D is formed with the dual structure having the trench and the via hole.

Referring to FIG. 2B, a first Ta-based layer 112 is formed on the surfaces of the metal line forming region D, whose surfaces include the second insulation layer 110 and the exposed surface of the lower metal line 102. The first Ta-based layer 112 is made of a Ta layer or a TaN layer, and is formed through CVD (chemical vapor deposition) or ALD (atomic layer deposition) to a thickness of 10˜50 Å.

Referring to FIG. 2C, by implementing a surface treatment on the first Ta-based layer 112, a TaSiₓN_{y} layer 114 is formed on the surface of the first Ta-based layer 112. The surface treatment is implemented through any one of rapid thermal processing (RTP), furnace annealing, and plasma treatment. The TaSiₓN_{y} layer 114 is formed to have a thickness of 5˜20 Å and to contain silicon of 1˜5 wt %. In the TaSiₓN_{y} layer 114, x has a range of 0.1˜0.9 and y has a range of 0.1˜0.9, provided x+y=1. When the first Ta-based layer 112 is a Ta layer, the TaSiₓN_{y} layer 114 is formed by surface-treating the Ta layer using a mixed gas of SiH₄ gas and nitrogen-containing gas or a mixed gas of SiH₂Cl₂ gas and nitrogen-containing gas. Also, when the Ta-based layer 112 is a TaN layer, the TaSiₓN_{y} layer 114 is formed by surface-treating the TaN layer using SiH₄ gas or SiH₂Cl₂ gas.

Referring to FIG. 2D, a second Ta-based layer 116, which is made of a Ta layer or a TaN layer, is formed on the TaSiₓN_{y} layer 114. This completes the formation of a diffusion barrier 118 with a triple-layered structure including a first Ta-based layer 112, a TaSiₓN_{y} layer 114 and a second Ta-based layer 116. The second Ta-based layer 116 is formed through CVD or ALD to a thickness of 10˜50 Å.

When the first and second Ta-based layers 112 and 116 are Ta layers, the diffusion barrier 118 of the present invention has the triple-layered structure of Ta/TaSiₓN_{y}/Ta. When the first and second Ta-based layers 112 and 116 are TaN layers, the diffusion barrier 118 of the present invention has the triple-layered structure of TaN/TaSiₓN_{y}/TaN.

Referring to FIG. 2E, a wiring metal line 120a is formed on the diffusion barrier 118 having the triple-layered structure. The wiring metal line is formed to a thickness capable of completely filling the metal line forming region D, and is preferably made of a copper layer.

Referring to FIG. 2F, the wiring metal line 120a and the diffusion barrier 118 are chemically and mechanically polished (CMP) until the second insulation layer 110 is exposed. This forms an upper metal line 120 that fills the damascene pattern D and comes into contact with the lower metal line 102.

Thereafter, although not shown in the drawings, a series of subsequent well-known processes are conducting, and the metal line of the semiconductor device according to the present invention is completely formed.

As is apparent from the above description of the present invention, when forming a metal line with a copper layer, a diffusion barrier is formed to have a triple layer structure of TaN/TaSiₓN_{y}/TaN or Ta/TaSiₓN_{y}/Ta in which a TaSiₓN_{y} layer is interposed between a first Ta-based layer and a second Ta-based layer. This diffusion barrier attains an improved interfacial screening effect when compared to a conventional single layer diffusion barrier. Thus, the triple layer structure by itself has improved characteristics.

Therefore, in the present invention, forming the diffusion barrier with a triple layer structure of Ta/TaSiₓN_{y}/Ta or TaN/TaSiₓN_{y}/TaN, prevents the contact resistance of a copper metal line from increasing and also prevents leakage current characteristics from being degraded. Thus leading to an improvement in the characteristics and reliability of a semiconductor device.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor device having a metal line, comprising:
a semiconductor substrate having an insulation layer formed with a metal line forming region;
a metal line formed to fill the metal line forming region of the insulation layer; and
a diffusion barrier formed between the metal line and the insulation layer, the diffusion barrier having a structure in which a TaSiₓN_{y} layer is interposed between a first Ta-based layer and a second Ta-based layer.

2. The semiconductor device according to claim 1, wherein the metal line forming region has a structure including a trench or a trench and a via hole formed in the trench.

3. The semiconductor device according to claim 1, wherein the first and second Ta-based layers are made of a Ta layer or a TaN layer.

4. The semiconductor device according to claim 1, wherein the first and second Ta-based layers have a thickness of 10˜50 Å.

5. The semiconductor device according to claim 1, wherein, in the TaSiₓN_{y} layer, x has a range of 0.1˜0.9 and y has a range of 0.1˜0.9 provided x+y=1.

6. The semiconductor device according to claim 1, wherein the TaSiₓN_{y} layer has a thickness in the range of 5˜20 Å.

7. The semiconductor device according to claim 1, wherein the TaSiₓN_{y} layer contains silicon of 1˜5 wt %.

8. The semiconductor device according to claim 1, wherein the metal line includes copper.

9. A method for forming a metal line in a semiconductor device, comprising the steps of:
forming an insulation layer having a metal line forming region on a semiconductor substrate;
forming a diffusion barrier on a surface of the metal line forming region and on a surface of the insulation layer, wherein the diffusion barrier has a structure in which a TaSiₓN_{y} layer is interposed between a first Ta-based layer and a second Ta-based layer;
forming a metal layer on the diffusion barrier to fill the metal line forming region; and
removing the metal layer and the diffusion barrier until the insulation layer is exposed.

10. The method according to claim 9, wherein the metal line forming region is formed to have a structure including a trench or a trench and a via hole formed in the trench.

11. The method according to claim 9, wherein the first and second Ta-based layers are made of a Ta layer or a TaN layer.

12. The method according to claim 9, wherein the first and second Ta-based layers are formed to have a thickness in the range of 10˜50 Å.

13. The method according to claim 9, wherein, in the TaSiₓN_{y} layer, x has a range of 0.1˜0.9 and y has a range of 0.1˜0.9 provided x+y=1.

14. The method according to claim 9, wherein the TaSiₓN_{y} layer is formed to have a thickness in the range of 5˜20 Å.

15. The method according to claim 9, wherein the TaSiₓN_{y} layer is formed to contain silicon of 15 wt %.

16. The method according to claim 9, wherein the TaSiₓN_{y} layer is formed by surface-treating the first Ta-based layer.

17. The method according to claim 16, wherein the first Ta-based layer is a Ta layer, and the TaSiₓN_{y} layer is formed by surface-treating the Ta layer using SiH₄ gas and nitrogen-containing gas or SiH₂Cl₂ gas and nitrogen-containing gas.

18. The method according to claim 16, wherein the Ta-based layer is a TaN layer, and the TaSiₓN_{y} layer is formed by surface-treating the TaN layer using SiH₄ gas or SiH₂Cl₂ gas.

19. The method according to claim 17, wherein the surface treatment is implemented through any one of a rapid thermal processing (RTP), a furnace annealing, and a plasma treatment.

20. The method according to claim 9, wherein the metal layer includes copper.
